(19) United States
(12) Patent Application Publication
(10) Pub. No.: US 2008/0308908 A1
(43) Pub. Date: Dec. 18, 2008

(54) Nitride semiconductor device and method for producing nitride semiconductor device

(75) Inventor: Hirotaka Otake, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/155,923

(22) Filed: Jun. 11, 2008

(30) Foreign Application Priority Data
Jun. 12, 2007 (JP) 2007-154893

(51) Int. Cl. H01L 29/20; H01L 21/20

(52) U.S. Cl. 257/615; 438/483; 257/E21.098

(57) ABSTRACT

A nitride semiconductor device of the present invention includes: a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure formed with a first trench and a second trench, the first trench penetrating the second layer from the third layer and reaching at least the first layer, and the second trench having a side wall extending from the first, second, to third layers and being different from the first trench; a surface insulating film containing at least silicon nitride formed such that the surface insulating film covers the surface of the first trench; a gate insulating film formed on the side wall of the second trench such that the gate insulating film extends over the first, second, and third layers; and a gate electrode formed such that the gate electrode is opposed to the side wall of the second trench with the gate insulating film sandwiched between the gate electrode and the side wall.

### BACKGROUND OF THE INVENTION

1. Field of the Invention

The present invention relates to a nitride semiconductor device using a Group III nitride semiconductor and a manufacturing method thereof.

2. Description of Related Art

Conventionally, a power device using a silicon semiconductor is used for a power amplifier circuit, a power supply circuit, a motor drive circuit, or the like.

However, from theoretical limitations of the silicon semiconductor, high withstand voltage, low resistance, and high speed of the silicon device have nearly reached their limits, which leads to difficulties in satisfying market needs.

Therefore, consideration has been given to the development of a nitride semiconductor device having characteristics such as high withstand voltage, high-temperature operation, a large current density, high-speed switching, low on-resistance, and the like.

FIG. 7 is a diagrammatic sectional view for describing the structure of a conventional field effect transistor (nitride semiconductor device) using a group III nitride semiconductor.

This field effect transistor 80 includes a sapphire substrate 81 and a laminated structure 93 having an npn structure comprising an undoped GaN layer 82, an n type GaN layer 83, a p type GaN layer 84, and an n type GaA layer 85 which are laminated from the side of the sapphire substrate 81 in this order. In the laminated structure portion 93, a mesa-like laminated portion 92 is formed by etching from the top surface of the n type GaN layer 85 up to the middle of the n type GaN layer 83. Both side surfaces of this mesa-like laminated portion 92 are formed into inclined surfaces 91 inclined at a predetermined inclination angle with respect to the lamination interfaces of the laminated structure portion 93. On the surface (including the inclined surfaces 91) of the mesa-like laminated portion 92 and the surface of the n type GaN layer 83 exposed by etching, a gate insulating film 86 made of SiO₂ (silicon oxide) is formed. In the gate insulating film 86, contact holes for partially exposing the n type GaN layer 85 and the n type GaN layer 83 are formed. On the top surface of the n type GaN layer 85 exposed from the contact hole, a source electrode 88 is formed. The source electrode 88 is electrically connected to the n type GaN layer 85. On the other hand, on the upper surface of the n type GaN layer 83 exposed from the contact hole, a drain electrode 89 is formed. The drain electrode 89 is electrically connected to the n type GaN layer 83. On the gate insulating film 86, at the portions opposed to the inclined surfaces 91, gate electrodes 87 are formed. Then, the source electrode 88, the drain electrode 89, and the gate electrode 87 are insulated from each other by interposition of interlayer dielectric films 90 made of polyimide between each of the adjacent electrodes.

In the field effect transistor 80, the surface of a mesa-like laminated portion 92 as a part of a path connecting the source electrode and the drain electrode by the shortest distance on the surface of the laminated structure portion 93 is covered with the gate insulating film 86, and as described above, the gate insulating film 86 is made of SiO₂.

However, in the structure in which SiO₂ is in contact with the surface of the laminated structure portion 93 made of a group III nitride semiconductor, the interface charge increases. Therefore, when the transistor is off, the current (off-leak current) flowing in the source electrode from the drain electrode is high.

### SUMMARY OF THE INVENTION

An object of the present invention is to provide a nitride semiconductor device using a group III nitride semiconductor which can reduce the off-leak current and a method for producing the same.

A nitride semiconductor device of the present invention includes a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure formed with a first trench and a second trench, the first trench penetrating the second layer from the third layer and reaching at least the first layer, and the second trench having a side wall extending from the first, second, to third layers and being different from the first trench, a surface insulating film containing at least silicon nitride formed such that the surface insulating film covers the surface of the first trench, a gate insulating film formed on the side wall of the second trench such that the gate insulating film extends over the first, second, and third layers, and a gate electrode formed such that the gate electrode is opposed to the side wall of the second trench with the gate insulating film sandwiched between the gate electrode and the side wall.

According to this configuration, by laminating the n type first layer, the second layer containing a p type dopant, and the n type third layer, nitride semiconductor laminated structures having an npn structure is formed. In the nitride semiconductor laminated structure, first trench which penetrates the second layer from the third layer and reaches at least the first layer is formed. The surface of the first trench is covered with surface insulating film containing at least silicon nitride. In addition, in the nitride semiconductor structure portion, second trench which have side wall extending from the first to third layers and is different from the first trench is formed. On the side wall of the second trench, gate insulating film is arranged across the first through third layers. Portions near the interface between the side wall of the second trench at the second layer and the gate insulating film form channel region, and the gate electrode is opposed to the channel region with the gate insulating film sandwiched between the gate electrode and the side wall.

In the nitride semiconductor device, for example, the drain electrode is provided such that the drain electrode is electrically connected to the first layer inside the first trench. In the nitride semiconductor laminated structure, the source electrode is provided such that the source electrode is electrically connected to the third layer of the laminated portion of the first, second and third layers sandwiched by the first trench and the second trench. Accordingly, a vertical MIS (Metal Insulator Semiconductor) field effect transistor is formed. In addition, the drain electrode and the source electrode are electrically connected to the first layer and the third layer, respectively, and two or more semiconductor layers having different compositions or containing different dopants may be laminated between these electrodes and the semiconductor layer.

In the MIS field effect transistor, the drain electrode is provided inside the first trench, so that the path connecting the source electrode and the drain electrode by the shortest distance on the surface of the nitride semiconductor laminated structure includes the surface of the first trench. The surface of the first trench is covered with a surface insulating film containing at least silicon nitride. Therefore, the interface charge in the region between the source electrode and the drain electrode can be suppressed. As a result, the off-leak current can be reduced. In other words, in the transistor using the nitride semiconductor device of the present invention, the off-leak current can be reduced. Of course, since the nitride semiconductor device is made of a group III nitride semiconductor, and accordingly, characteristics such as a high withstand voltage, a high-temperature operation, large current density, high-speed switching, and low on-resistance can also be achieved as compared to a device made of a silicon semiconductor.

The group III nitride semiconductor is a semiconductor obtained by compounding a group III element and nitrogen, and typical examples are aluminum nitride (AlN), gallium nitride (GaN), and indium nitride (InN). Generally, it can be expressed as AlₓIn_{y}Ga_{1-x-y}N (0≦x≦1, 0≦y≦1, 0≦x+y≦1).

Next, operations of the above-described MIS field effect transistor is described. For example, first, a bias voltage is applied to between the source and the drain such that the drain electrode is positive. Accordingly, a pn junction at the interface between the first and second layer is applied a reverse voltage, and as a result, between the third layer and the first layer, that is, between the source and the drain is nonconductive state (reverse bias state). From this state, when a bias voltage equal to or more than a predetermined voltage value (gate threshold voltage) being positive to the potential of the source electrode regarded as a reference potential is applied to the gate electrode, near the interface between the side wall of the second trench at the second layer and the gate insulating film, electrons are induced to form an inversion layer (channel). Via this inversion layer, conduction is provided between the source and the drain, and accordingly, a transistor operation of this MIS field effect transistor is realized.

In the nitride semiconductor device, it is preferable that the gate insulating film is made of a combination of silicon nitride and silicon oxide, and silicon nitride is in direct contact with side wall of the second trench. In this structure, the surface of the side wall portion of the second trench is covered with silicon nitride, so that the interface charge at the gate portion of the nitride semiconductor device can also be suppressed. Therefore, preferential flow of a leak current (off-leak current) on the second trench surfaces due to the presence of interface charge when the nitride semiconductor device is off can be prevented. As a result, further leak reduction is realized.

A method for producing a nitride semiconductor device of the present invention includes a laminating step for forming a nitride semiconductor laminated structure having a laminated structure comprising an n type first layer, a second layer containing a p type dopant, and an n type third layer, each layer of the laminated structure made of a group III nitride semiconductor, a first trench forming step for forming a first trench penetrating the second layer from the third layer and reaching at least the first layer, a surface insulating film forming step for forming a surface insulating film containing at least silicon nitride so as to cover the surface of the first trench, a second trench forming step for forming a second trench having a side wall extending from the first, second, to third layers, a gate insulating film forming step for forming a gate insulating film on the side wall of the second trench so as to extend over the first, second, and third layers; and a gate electrode forming step for forming a gate electrode so as to be opposed to the side wall of the second trench with the gate insulating film sandwiched between the gate electrode and the side wall. According to this method, the above-described nitride semiconductor device can be manufactured. For example, the method of the present invention further includes a drain electrode forming step for forming the drain electrode so as to be electrically connected to the first layer inside the first trench; and a source electrode forming step for forming the source electrode so as to be electrically connected to the third layer of a laminated portion comprising of the first, second, and third layers sandwiched by the first trench and the second trench in the nitride semiconductor laminated structure, whereby the above-described MIS field effect transistor can be manufactured.

In the method for producing the nitride semiconductor device, it is preferable that the second trench forming step includes a step of forming the second trench by etching using a mask containing at least silicon nitride formed so as to cover at least the surface of the first trench, and the surface insulating film forming step is a step of forming the surface insulating film including the mask used for forming the second trench.

According to this method, the mask containing at least silicon nitride used at the second trench forming step is included in the surface insulating film to be formed at the surface insulating film forming step. Therefore, the step of removing the mask after the second trench forming step can be omitted, so that the production process of the nitride semiconductor device can be simplified. Further, before the second trench forming step, the surface of the first trench is covered with silicon nitride, so that the material and film thickness of the gate insulating film to be formed on the side wall of the second trench can be determined without depending on the surface insulating film of the first trench.

In the method for producing the nitride semiconductor device, it is preferable that the third layer has the top surface parallel to the lamination interface in the nitride semiconductor laminated structure, and the mask is formed so as to cover the top surface and the mask covering the top surface is left after the second trench forming step.

In the method described above, the mask covering the top surface of the third layer is left after the second trench forming step. Therefore, by properly controlling the thickness of the mask, the gate withstand voltage can be improved. In addition, this mask thickness control can be performed regardless of the film thickness control of the gate insulating film. Therefore, the film thickness of the gate insulating film at the gate portion is not increased. Further, when the gate insulating film forming step is a step of forming gate insulating film so as to cover the mask covering the top surface, the thickness of the insulating film covering the top surface of the third layer can be increased to a thickness of the mask thickness plus the gate insulating film thickness. As a result, the gate withstand voltage can be further improved.

In the method for producing the nitride semiconductor device, it is preferable that the mask includes a silicon nitride film in contact with the surface of the first trench. According to this method, the mask including the silicon nitride film in contact with the surface of the first trench is included in the surface insulating film to be formed at the surface insulating film forming step. Therefore, in a transistor using the produced nitride semiconductor device, the interface charge between the source and the drain can be further suppressed.

It is preferable that the method for producing the nitride semiconductor device further includes a step of wet-etching the surface portion of the mask after the second trench forming step. By wet-etching the surface portion of the mask, the surface of the mask can be smoothed.

These and other objects, features and effects of the present invention will be more apparent from the following embodiments described with reference to the accompanying drawings.

### BRIEF DESCRIPTION OF THE SEVERAL VIEWS OF THE DRAWING

FIG. 1 is a diagrammatic sectional view for describing a structure of a field effect transistor of an embodiment of the present invention;

FIG. 2A is a diagrammatic sectional view showing a method for producing the field effect transistor of FIG. 1 in order of steps;

FIG. 2B is a diagrammatic sectional view of the next step of FIG. 2A;

FIG. 2C is a diagrammatic sectional view of the next step of FIG. 2B;

FIG. 2D is a diagrammatic sectional view of the next step of FIG. 2C;

FIG. 2E is a diagrammatic sectional view of the next step of FIG. 2D;

FIG. 2F is a diagrammatic sectional view of the next step of FIG. 2E;

FIG. 2G is a diagrammatic sectional view of the next step of FIG. 2F;

FIG. 2H is a diagrammatic sectional view of the next step of FIG. 2G;

FIG. 3 is a diagrammatic sectional view showing a variation of the field effect transistor shown in FIG. 1;

FIG. 4 is a diagrammatic sectional view showing GaN nitride semiconductor laminated structures of Example 1 and Comparative example 1;

FIG. 5 is a diagram showing results of leak current measurement of the GaN nitride semiconductor laminated structures of Example 1 and Comparative example 1.

FIG. 6 is a diagram showing results of gate withstand voltage measurement of field effect transistors of Example 2 and Comparative example 2;

FIG. 7 is a diagrammatic sectional view for describing a structure of a conventional field effect transistor.

### DETAILED DESCRIPTION OF THE INVENTION

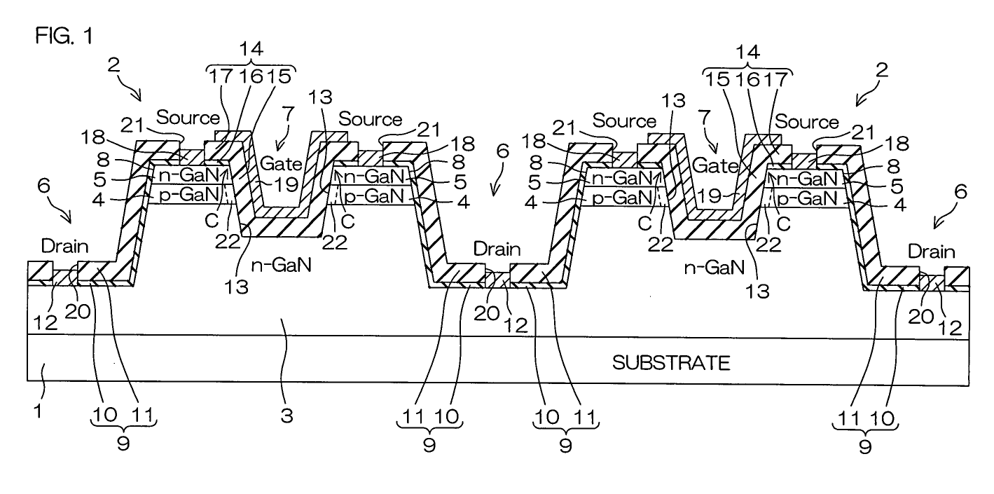

FIG. 1 is a diagrammatic sectional view for describing the structure of an MIS field effect transistor of an embodiment of the present invention.

This field effect transistor (nitride semiconductor device) includes a substrate 1 and a nitride semiconductor laminated structure 2 comprising of a GaN compound semiconductor layer grown on the substrate 1.

As the substrate 1, for example, an insulative substrate such as a sapphire substrate or a conductive substrate such as a GaN substrate, a ZnO substrate, a Si substrate, a GaAs substrate, or a SiC substrate can be used.

The nitride semiconductor laminated structure 2 includes an n type GaN layer 3 (first layer), a p type GaN layer 4 (second layer), and an n type GaN layer 5 (third layer), and these GaN layers are laminated in this order. In the nitride semiconductor laminated structures 2, drain trenches 6 (first trenches) and gate trenches 7 (second trenches) different from the drain trenches 6, each having substantially trapezoid sectional shapes which penetrate the p type GaN layer 4 from the n type GaN layer 5 and reach the middle of the n type GaN layer 3, are formed. Accordingly, the nitride semiconductor laminated structures 2 are formed in substantially trapezoid (mesa-like) sectional shapes at the portion sandwiched between the drain trench 6 and the gate trench 7, and by this mesa-like portion, the drain trench 6 in which the drain electrode 12 (described later) formed and the gate trench 7 in which a gate electrodes 19 (described later) is formed are partitioned.

The drain trenches 6 and the gate trenches 7 are formed alternately in a stripe pattern in the nitride semiconductor laminated structures portions 2, and are formed so that the depth from the surface of the n type GaN layer to the bottom surface of the drain trench 6 is larger than the depth to the bottom surface of the gate trench 7. For example, when the film thicknesses of the n type GaN layer 5 and the p type GaN layer 4 are both 0.5 μm, the depth from the surface of the n type GaN layer 5 to the bottom surface of the drain trench 6 is 1.8 to 2.0 μm, and the depth to the bottom surface of the gate trench 7 is 1.5 to 1.8 μm. In this field effect transistor, the portions sandwiched between the drain trenches 6 adjacent to each other across the gate trenches 7 form unit cells, each, and FIG. 1 describes two of the unit cells.

On the bottom surface of the drain trench 6, a drain electrode 12 is formed in contact with it. The drain electrode 12 is electrically connected to the n type GaN layer 3. On the top surface of the n type GaN layer 5, a source electrode 18 is formed in contact with it. The source electrode 18 is electrically connected to the n type GaN layer 5.

As the drain electrode 12 and the source electrode 18, for example, a laminated structure made of Ti/Al (lower layer/upper layer) can be applied. Alternately, the drain electrode 12 and the source electrode 18 can be made of, for example, Mo or an Mo compound (for example, molybdenumsilicide), Ti or a Ti compound (for example, titanium silicide), or W or a W compound (for example, tungsten silicide). When the drain electrode 12 and the source electrode 18 are such a material, excellent contact can be achieved for wiring (not shown) for applying a bias voltage to these electrodes can be made from the drain electrode 12 and the source electrode 18.

The side wall of the drain trench 6 forms a wall surface 8 extending from the n type GaN layer 3, the p type GaN layer 4, to the n type GaN layer 5.

The nitride semiconductor laminated structure 2 is formed by means of, for example, so-called MOCVD (Metal Oxide Chemical Vapor Deposition) on the substrate 1. For example, when a substrate 1 whose principal surface is a c-plane (0001) is used, the nitride semiconductor laminated structure 2 grown by epitaxial growth on this substrate 1, that is, the n type GaN layer 3, the p type GaN layer 4, and the n type GaN layer 5 are laminated by using c-planes (0001) as principal surfaces. Therefore, the lamination interfaces of the nitride semiconductor laminated structure 2 and the top surface of the n type GaN layer 5 are c-planes (0001). Therefore, the drain trenches 6 formed so as to penetrate the lamination interfaces of the nitride semiconductor laminated structure 2 are formed so that their wall surfaces 8 is surfaces (planes other than c-planes) inclined in the range of 15 to 90 degrees with respect to the c-planes (0001). More specifically, the drain trenches 6 are formed so as to be nonpolar planes such as m-planes (10-10) or a-planes (11-20) or semipolar planes of (10-13), (10-11), and (11-22), or the like.

In regions covering the wall surfaces 8 and the entire regions of the bottom surfaces (except for the portions where the drain electrodes 12 are formed) of the drain trenches 6 and reaching the source electrodes 18 on the top surfaces of the n type GaN layer 5, surface insulating films 9 are formed. The surface insulating film 9 is formed of a laminated film in which a lower film 10 made of SiN (silicon nitride) in contact with the surface of the nitride semiconductor laminated structure 2 and an upper layer film 11 made of, for example, SiO₂ (silicon oxide) are laminated.

The lower layer film 10 and the upper layer film 11 are formed so that, for example, the film thickness of the lower layer film 10 is thinner than the film thickness of the upper layer film 11. For example, the film thickness of the lower layer film 10 is 50 to 500 angstroms, and the film thickness of the upper layer film 11 is 1000 to 5000 angstroms. Preferably, the film thickness of the lower layer film 10 is 100 to 200 angstroms, and the film thickness of the upper layer film 11 is 2000 to 3500 angstroms. The surface insulating film 9 is formed so that the thickness of the entire laminated film of the lower layer film 10 and the upper layer film 11 is thicker than the thicknesses of the drain electrode 12 and the source electrode 18 in the lamination direction of the nitride semiconductor laminated structure 2.

On the other hand, the side walls of the gate trench 7 form wall surfaces 13 opposed to the wall surfaces 8 of the drain trench 6 across the n type GaN layer 3, the p type GaN layer 4, and the n type GaN layer 5, and extending from the n type GaN layer 3, the p type GaN layer 4, to the n type GaN layer 5. The gate trench 7 is formed so as to penetrate the lamination interfaces of the nitride semiconductor laminated structure 2. Therefore, the wall surface 13 of the gate trench 7 is a surface (plane other than c-plane) inclined in the range of, for example, 15 to 90 degrees to the c-plane (0001), specifically, nonpolar plane such as m-plane (10-10) or a-plane (11-20) or semipolar plane such as (10-13), (10-11), or (11-22) similar to the wall surface 8 of the drain trench 6.

In regions covering the wall surfaces 13 and the entire regions of the bottom surfaces of the gate trenches 7 and reaching the source electrodes 18 on the top surfaces of the n type GaN layer 5, gate insulating films 14 are formed. The portion of this gate insulating film 14 opposed to the wall surface 13 and the bottom surface of the gate trench 7 is, for example, a single-layer film 15 made of SiO₂. On the other hand, the portion opposed to the top surface of the n type GaN layer 5 is a laminated film having a lower layer film 16 made of SiN and an upper layer film 17 made of SiO₂, for example. The upper layer film 17 continues to the single-layer film 15.

The lower layer film 16 and the upper layer film 17 are formed so as to have the same thicknesses as those of the lower layer film 10 and the upper layer film 11. The gate insulating film 14 is formed so that the film thickness of the entire laminated film comprising the lower layer film 16 and the upper layer film 17 is thicker than the height of the source electrode 18.

On the gate insulating film 14, a gate electrode 19 is formed so as to be opposed to the wall surfaces 13 and the entire region of the bottom surface of the gate trench 7 and the edges of the gate trench 7 on the top surface of the n type GaN layer 5 across the gate insulating film 14. As the gate electrodes 19, a conductive material such as Pt (platinum), Al (aluminum), Ni/Au (nickel/gold alloy), Ni/Ti/Au (nickel/titanium/gold alloy), Pd/Au (palladium/gold alloy), Pd/Ti/Au (palladium/titanium/gold alloy), Pd/Pt/Au (palladium/platinum/gold alloy), and polysilicon, or the like, can be applied.

In the drain trench 6, in the region sandwiched by the end faces of the surface insulating films 9 in contact with both side surfaces of the drain electrode 12, a contact opening 20 for contact with the drain electrode 12 is formed. On the other hand, on the n type GaN layer 5, in the region sandwiched between the end face of the surface insulating film 9 and the end face of the gate insulating film 14 which are in contact with one side surface and the other side surface of the source electrode 18, a contact opening 21 for contact with the source electrode 18 is formed.

In the p type GaN layer 4, the region near the interface between the wall surface 13 of the gate trench 7 and the gate insulating film 14 is a channel region 22 opposed to the gate electrode 19. In this channel region 22, an inversion layer is formed, which provides conduction between the n type GaN layer 3 and the n type GaN layer 5 when an appropriate bias voltage is applied to the gate electrode 19.

Next, operations of the field effect transistor is described.

A bias voltage is applied to between the source electrode 18 and the drain electrode 12 such that the drain electrode is positive. Accordingly, a pn junction at the interface between the n type GaN layer 3 and the p type GaN layer 4 is applied a reverse voltage, and as a result, between the n type GaN layer 5 and the n type GaN layer 3, that is, between the source and the drain is nonconductive state (reverse bias state). From this status, when a bias voltage equal to or more than a predetermined voltage value (gate threshold voltage) being positive to the potential of the source electrode 18 regarded as a reference potential is applied to the gate electrode 19, in the channel region 22 of the p type GaN layer 4, electrons are induced and an inversion layer (channel) is formed. Then, via this inversion layer, conduction is provided between the n type GaN layer 3 and the n type GaN layer 5. Thus, conduction is provided between the source and the drain. Accordingly, a transistor operation of this field effect transistor is realized.

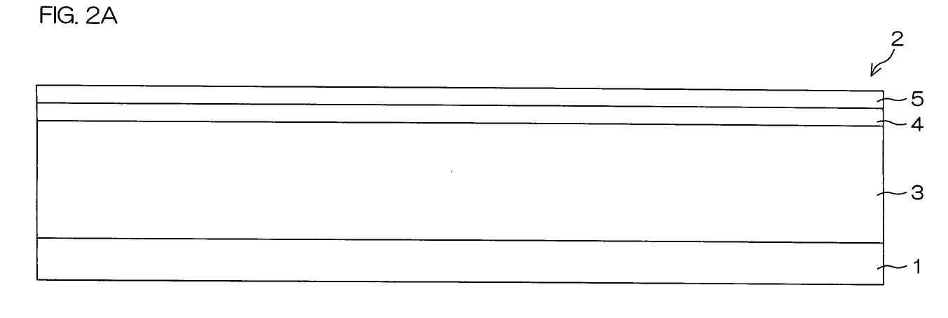

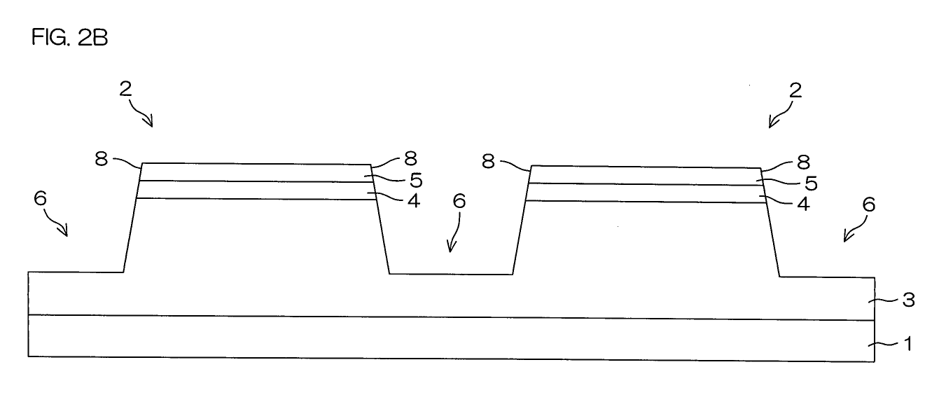

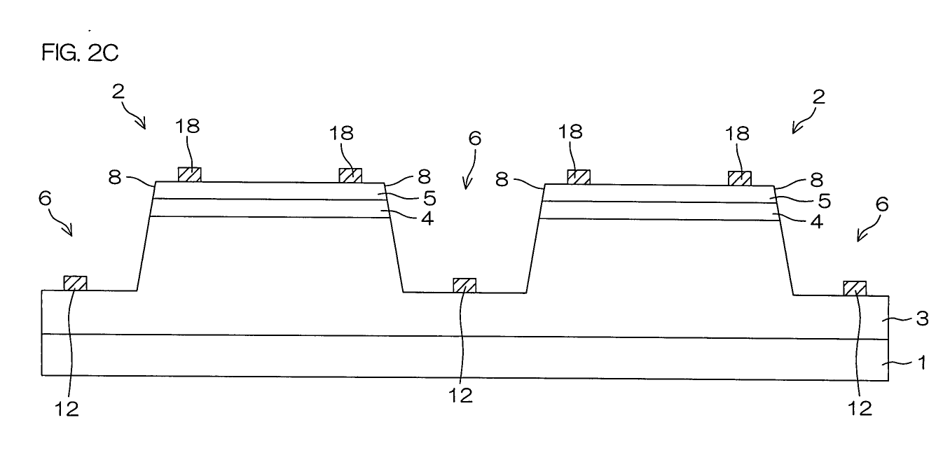

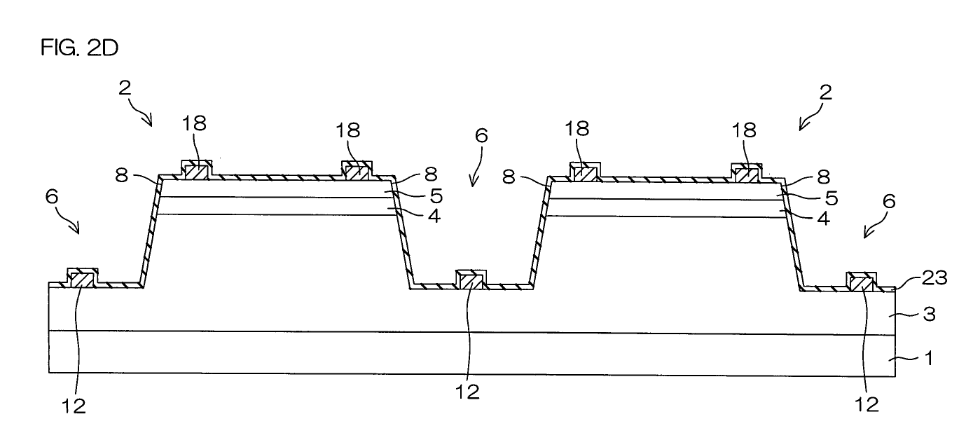

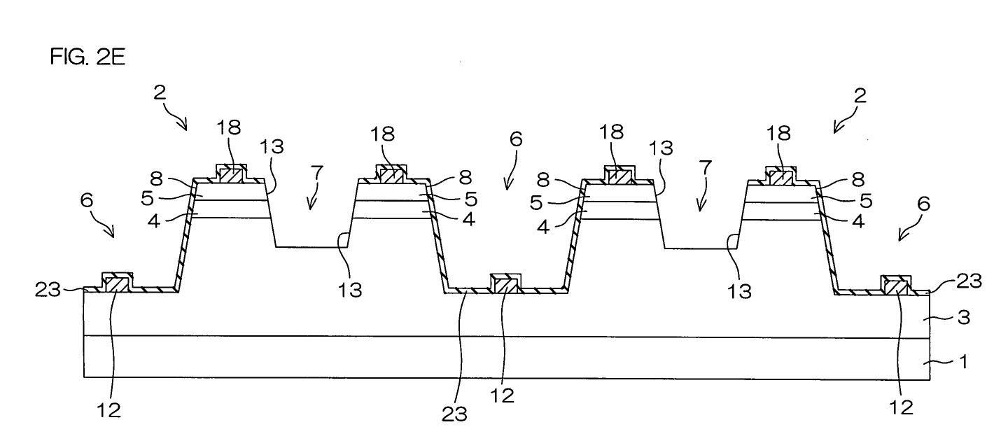

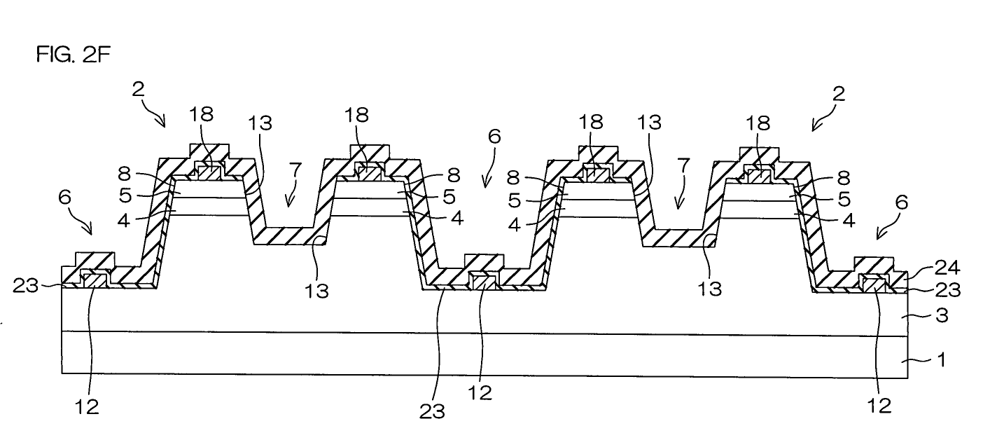

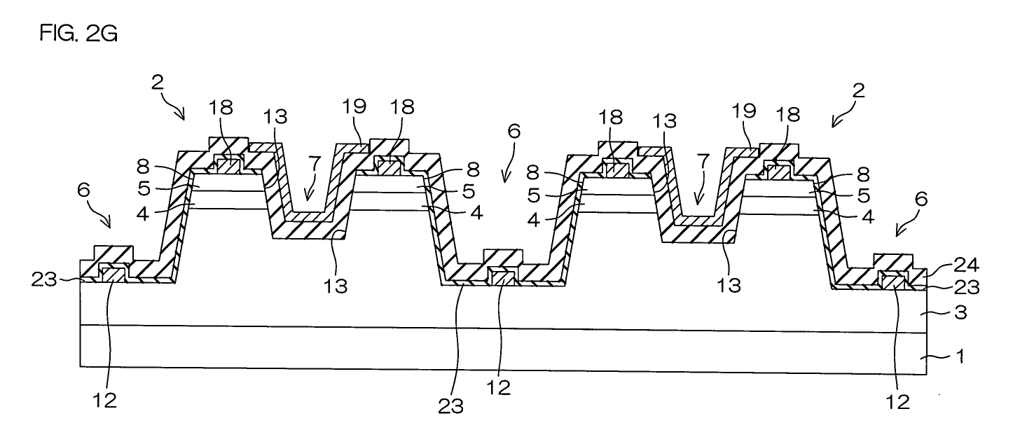

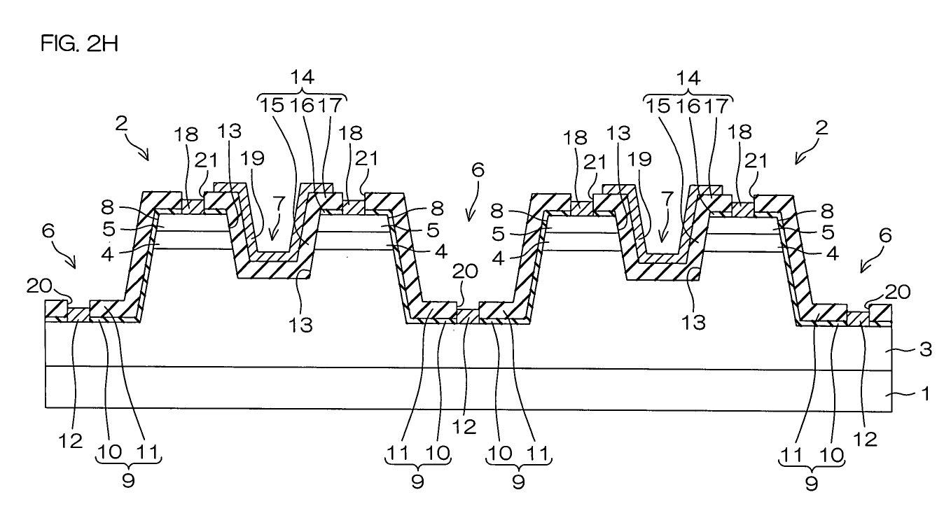

FIG. 2A through FIG. 2H are diagrammatic sectional views showing a method for producing the field effect transistor of FIG. 1 in order of steps.

To produce this field effect transistor, first, as shown in FIG. 2A, on the substrate 1, for example, by means of MOCVD using a c-plane (0001) as a growth principal surface, the n type GaN layer 3, the p type GaN layer 4, and the n type GaN layer 5 are grown in order. Thus, on the substrate 1, the nitride semiconductor laminated structures portions 2 having c-planes (0001) as lamination interfaces are formed. As an n type dopant for growing the n type GaN layer 3 and the n type GaN layer 5, for example, Si is used. As a p type dopant for growing the p type GaN layer 4, for example, Mg, C, or the like is used.

Next, as shown in FIG. 2B, drain trenches 6 are formed. The drain trenches 6 are formed by etching the nitride semiconductor laminated structures 2 in a stripe pattern so that wall surfaces 8 having plane orientation inclined in the range of 15 to 90 degrees to the c-plane (0001) are cut out. This etching is performed to a depth that penetrates the p type GaN layer 4 from the n type GaN layer 5 and reaches the middle of the n type GaN layer 3.

More specifically, for example, by a known photolithography, a photoresist (not shown) having openings in regions where the drain trenches 6 should be formed is formed, and then dry-etching is performed by using this photoresist as a mask. This dry-etching is performed by using, for example, a chlorine-based gas (for example, Cl₂, BCl₃, CCl₄, SiCl₄, or the like). Further, after the dry-etching, wet-etching for improving the wall surfaces 8 and the bottom surfaces of the drain trenches 6 which were damaged by the dry-etching may be performed as appropriate. For wet-etching, it is preferable that HF (hydrofluoric acid) or HCl (hydrochloric acid), or the like, is used. Accordingly, Si-based oxides and Ga oxides are removed and the wall surfaces 8 and the bottom surfaces of the drain trenches 6 can be smoothed, so that surfaces with less damage can be obtained. Instead of the wet-etching, low-damage dry-etching may also be applied.

Next, by a known photolithography technique, a photoresist (not shown) having openings in regions where the drain electrodes 12 and the source electrodes 18 should be formed is formed. Then, from above this photoresist, metals (for example, Ti and Al) to be used as materials of the drain electrodes 12 and the source electrodes 18 are sputtered by a sputtering method in order of Ti and Al. Thereafter, the photoresist is removed, and unnecessary portions (portions other than the drain electrodes 12 and the source electrodes 18) of the metals are lifted off together with the photoresist. By these operations, as shown in FIG. 2C, on the bottom surfaces of the drain trenches 6, drain electrodes 12 are formed in contact with these, and on the top surfaces of the n type GaN layer 5, source electrodes 18 are formed in contact with these. After the formation of the drain electrodes 12 and the source electrodes 18, thermal alloying (annealing) is performed, whereby the contact between the drain electrodes 12 and the n type GaN layer 3 and the contact between the source electrodes 18 and the n type GaN layer 5 form ohmic contact each.

Subsequently, as shown in FIG. 2D, an insulating film 23 made of SiN is formed so as to cover the wall surfaces 8 and the entire regions of the bottom surfaces of the drain trenches 6 and the top surfaces of the n type GaN layer 5. The insulating film 23 is formed by, for example, ECR sputtering (Electron Cyclotron Resonance sputtering) so as to have the same thickness as that of the lower layer film 10 and the lower layer film 16. Accordingly, the drain electrodes 12 and the source electrodes 18 are covered by the insulating film 23.

After the insulating film 23 is formed, as shown in FIG. 2E, gate trenches 7 are formed. The gate trenches 7 are formed by etching the nitride semiconductor laminated structures 2 in a stripe pattern so that wall surfaces 13 with plane orientation inclined in the range of 15 to 90 degrees to the c-plane (0001) between source electrodes 18 adjacent to each other on the n type GaN layer 5 are cut out. In this etching, the insulating film 23 is used as a mask, and the etching depth (depth of the gate trenches 7) is controlled so as to be shallower than the depth of the drain trenches 6.

More specifically, for example, by a known photolithography technique, openings are formed in regions of the insulating film 23 where the gate trenches 7 should be formed, and then, dry-etching is performed by using this insulating film 23 as a mask. Dry-etching is performed by using, for example, a chlorine-based gas (for example, Cl₂, BCl₃, CCl₄, SiCl₄, or the like) as in the case of the drain trenches 6. Further, after dry-etching, wet-etching for improving the wall surfaces 13 and the bottom surfaces of the gate trenches 7 and the surface layer portion of the insulating film 23 used as a mask which were damaged by the dry-etching may be performed as appropriate. For wet-etching, HF (hydrofluoric acid) or HCl (hydrochloric acid), or the like, is used. Accordingly, Si-based oxides and Ga oxides are removed and the surfaces of the wall surfaces 13, the bottom surfaces and the insulating film 23 of the gate trenches 7 can be smoothed, so that surfaces with less damage can be obtained. By reducing the damage of the wall surfaces 13, the crystal state of the channel regions 22 can be maintained excellently, and the interfaces between the wall surfaces 13 and the gate insulating films 14 can be made excellent, so that the interface state can be reduced. Accordingly, the channel resistance can be reduced and the leak current can be suppressed.

Next, as shown in FIG. 2F, while the insulating film 23 used as a mask is left intact on the wall surfaces 8 and the bottom surfaces of the drain trenches 6 and the top surfaces of the n type GaN layer 5, an insulating film 24 made of, for example, SiO₂ is formed. This insulating film 24 is formed so as to cover the insulating film 23 and the wall surfaces 13 and the entire regions of the bottom surfaces of the gate trenches 7 by, for example, ECR sputtering. The insulating film 24 is formed so as to have the same thickness as that of the single-layer film 15.

Subsequently, by a known photolithography technique, a photoresist (not shown) having openings in regions where the gate electrodes 19 should be formed is formed. Then, from above this photoresist, a metal (for example, a conductive material described above) to be used as a material of the gate electrodes 19 is sputtered by a sputtering method. Thereafter, the photoresist is removed and unnecessary portions of the metal (portions other than the gate electrodes 19) are lifted off together with the photoresist. By these operations, as shown in FIG. 2G, gate electrodes 19 opposed to the wall surfaces 13 and the entire regions of the bottom surfaces of the gate trenches 7 and edges of the gate trenches 7 on the top surfaces of the n type GaN layer 5 are formed.

Then, as shown in FIG. 2H, in the laminated insulating film comprising the insulating film 23 and the insulating film 24, contact openings 20 and contact openings 21 from which the drain electrodes 12 and the source electrodes 18 are exposed, respectively, are formed. These openings are formed by dry-etching using, for example, CF₄ (carbon tetrafluoride). The insulating film 23 and the insulating film 24 cover the wall surfaces 8 and the entire regions of the bottom surfaces of the drain trenches 6, and further, the portions reaching the source electrodes 18 on the top surfaces of the n type GaN layer 5 become surface insulating films 9. On the other hand, portions which cover the wall surfaces 13 and the entire regions of the bottom surfaces of the gate trenches 7 and further reach the source electrodes 18 on the top surfaces of the n type GaN layer 5 become gate insulating films 14. The field effect transistor having the structure shown in FIG. 1 is thus obtained.

The portions sandwiched by the drain trenches 6 adjacent to each other across the gate trench 7 in the plurality of nitride semiconductor laminated structures 2 formed on the substrate 1 form unit cells, each. The gate electrodes 19, the drain electrodes 12, and the source electrodes 18 of the plurality of nitride semiconductor laminated structures 2 are mutually connected at positions not shown, each. The drain electrode 12 can be shared by nitride semiconductor laminated structures 2 adjacent to each other.

As described above, according to this embodiment, in the regions which cover the wall surfaces 8 and the entire regions of the bottom surfaces (except for the portions where the drain electrodes 12 are formed) of the drain trenches 6 and reach the source electrodes 18 on the top surfaces of the n type GaN layer 5, surface insulating films 9 are formed. Between the lower layer film 10 made of SiN and the upper layer film 11 made of SiO₂ of the surface insulating film 9, the lower layer film 10 is formed in contact with the surface of the nitride semiconductor laminated structure 2.

The lower layer film 10 is formed in contact with the path connecting the source electrode 18 and the drain electrode 12 by the shortest distance on the surface of the nitride semiconductor laminated structure 2, so that the interface charge in the region between the source electrode and the drain electrode can be suppressed. As a result, the off-leak current of the field effect transistor can be reduced. Of course, since the field effect transistor is made of a group III nitride semiconductor, as compared to a device made of a silicon semiconductor, characteristics such as high withstand voltage, a high-temperature operation, large current density, high-speed switching, and low on-resistance can be achieved.

This lower layer film 10 is made by using the insulating film 23 used as a mask when forming the gate trenches 7. Therefore, in the production process of the field effect transistor, after the formation of the gate trenches 7, it becomes unnecessary to remove the mask. Accordingly, the step of removing the mask can be omitted, so that the production process of the field effect transistor can be simplified.

The insulating film 23 that is not removed but remains in that covers the top surfaces of the n type GaN layer 5, and on this insulating film 23, the insulating film 24 is further formed. Accordingly, in the gate insulating films 14 in the produced field effect transistor, the thickness of the portion opposed to the top surface of the n type GaN layer 5 is increased to a thickness of the thickness of the lower layer film 16 (portion formed by the insulating film 23) plus the thickness of the upper layer film 17 (portion formed by the insulating film 24). Therefore, in the case of the reverse bias state, even when electric field concentration occurs in the edges of the gate trenches 7 on the top surfaces of the n type GaN layer 5 (for example, the portions indicated by the arrows C in FIG. 1), the film thickness of the gate insulating film 14 at the portion where this electric field concentration occurs is thick, so that occurrence of a breakdown at this portion can be prevented. As a result, the gate withstand voltage of the field effect transistor can be improved.

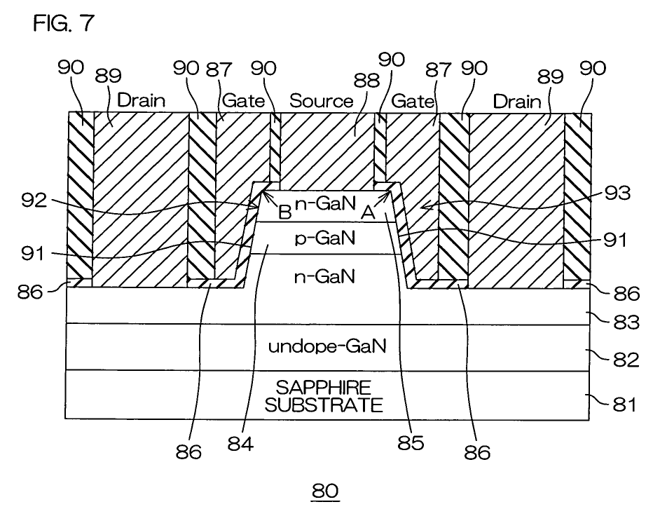

As describe above, for example, in the field effect transistor 80 shown in FIG. 7, the thickness of the gate insulating film 86 covering the surface of the mesa-like laminated portion 92 at the edges of the top surface of the n type GaN layer 85 (portions shown by the arrows A and B in FIG. 7) are thinner than thickness of other portions. Therefore, in a reverse bias status, breakdown easily occurs at these portions at the edges of the top surface of the n type GaN layer 85, so that the gate withstand voltage is lowered. Therefore, a measure in which the gate withstand voltage is improved by increasing the film thickness of the gate insulating film 86 is considered, however, if the film thickness is uniformly increased, it poses another problem in which the gate threshold voltage is high. Therefore, a nitride semiconductor device which can improve the gate withstand voltage without changing the film thickness of the gate insulating film is desired.

In addition, this improvement in gate withstand voltage is realized not by uniformly increasing the thickness of the gate insulating film 14 but by controlling only the thickness of the portion opposed to the top surface of the n type GaN layer 5. Therefore, by controlling the portion opposed to the channel region 22 in the gate insulating film 14 to a proper thickness, the gate threshold voltage can be adjusted to a proper value.

An embodiment of the present invention is described above, however, the present invention can be carried out according to other embodiments.

For example, in the above-described embodiment, the nitride semiconductor laminated structure 2 includes at least an n type group III nitride semiconductor layer, a conductive group III nitride semiconductor layer containing a p type dopant, and an n type group III nitride semiconductor layer, and for example, in addition to the n type GaN layer 3, the p type GaN layer 4, and the n type GaN layer 5, between the substrate 1 and the n type GaN layer 3, an n type AlGaN layer, or the like, may be formed in contact with these.

In the above-described embodiment, the drain trenches 6 are formed to a depth which penetrates the p type GaN layer 4 from the n type GaN layer 5 and reach the middle of the n type GaN layer 3, however, the depth is not especially limited as long as the drain electrodes 12 and the n type GaN layer 3 can be electrically connected, and for example, in a configuration in which an n type AlGaN layer is further formed between the substrate 1 and the n type GaN layer 3, the drain trenches may be formed to a depth which penetrate the n type GaN layer 3 and reach the middle of the n type AlGaN layer. It is also allowed that the source electrodes 18 are not in contact with the n type GaN layer 5 as long as the n type GaN layer 5 and the source electrodes 18 can be electrically connected to each other, and for example, a GaN layer may be further interposed between the source electrodes 18 and the n type GaN layer 5.

In the above-described embodiment, the drain electrodes 12 and the source electrodes 18 are electrically connected to the n type GaN layer 3 and the n type GaN layer 5, respectively, however, as another embodiment, the arrangement positions of the drain electrodes 12 and the source electrodes 18 may be switched with each other.

In the embodiments described above, as a method for growing the nitride semiconductor laminated structure 2, MOCVD is applied, however, the method is not especially limited as long as the n type GaN layer 3, the p type GaN layer 4, and the n type GaN layer 5 can be grown, and for example, methods such as LPE (Liquid Phase Epitaxy), VPE (Vapor Phase Epitaxy), and MBE (Molecular Beam Epitaxy) may be applied.

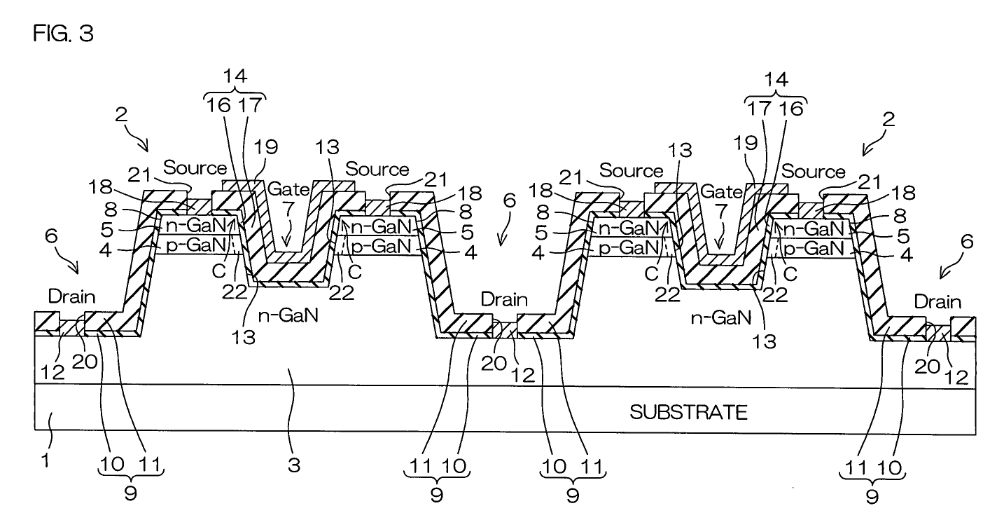

Further, in the above-described embodiment, the portion of the gate insulating film 14 opposed to the wall surfaces 13 and the bottom surface of the gate trench 7 is formed of, for example, a single-layer film 15 made of SiO₂, however, for example, as shown in FIG. 3, in the entirety of the region that covers the wall surfaces 13 and the entire region of the bottom surface of the gate trench 7 and further reach the source electrode 18 on the top surface of the n type GaN layer 5 it may be formed of a laminated film in which a lower layer film 16 made of SiN in contact with the surface of the nitride semiconductor laminated structure 2 and an upper layer film 17 made of SiO₂ are laminated. According to this structure, the wall surfaces 13 of the gate trench 7 are covered by SiN, so that the interface charge at the gate portion in the field effect transistor can also be suppressed. As a result, preferential flow of a leak current (off-leak current) in the wall surfaces 13 of the gate trench 7 due to the presence of the interface charge when the field effect transistor is off can be prevented, so that further leak reduction is realized.

### EXAMPLES

Next, the present invention will be described based on Examples and Comparative examples, however, the invention should not be limited by the following examples.

### Example 1

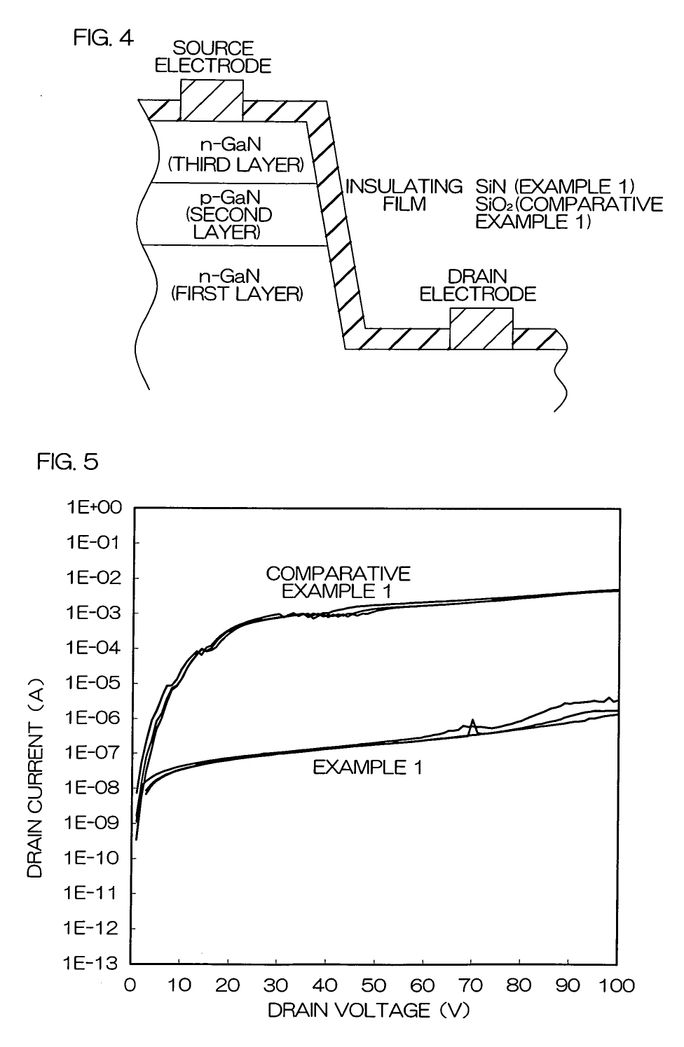

On a substrate, a GaN nitride semiconductor laminated structure formed of an npn laminated structure in which an n type GaN layer (first layer), a p type GaN layer (second layer), and an n type GaN layer (third layer) were laminated by MOCVD was manufactured. Then, in this GaN nitride semiconductor laminated structure, from the surface of the n type GaN layer (third layer), a trench which penetrates the p type GaN layer (second layer) and reaches the middle of the n type GaN layer (first layer) was formed. Then, on the bottom surface of this trench, a drain electrode (Ti/Al laminated structure) was formed, and on the top surface of the n type GaN layer (third layer), a source electrode (Ti/Al laminated structure) was formed. Then, between the source and the drain, an insulating film (film thickness: 100 angstroms) made of SiN was formed so as to cover the bottom surface and the side surfaces of the trench and the top surface of the n type GaN layer (third layer) (see FIG. 4).

### Comparative Example 1

A GaN nitride semiconductor laminated structure was manufactured which had the same construction as that of Example 1 except that an insulating film (film thickness: 2000 angstroms) made of SiO₂ was formed between the source and the drain so as to cover the bottom surface and the side surfaces of the trench and the top surface of the n type GaN layer (third layer) (see FIG. 4).

### Measurement of Leak Current

In the GaN nitride semiconductor laminated structures of Example 1 and Comparative example 1, a bias voltage (drain voltage) was applied between the source and the drain such that the drain electrode was positive. The value of a leak current (drain current) when the value of this drain voltage was changed was measured. The results of the measurement are shown in FIG. 5. As shown in FIG. 5, when the drain voltage was 20V, the drain current flowing in the GaN nitride semiconductor laminated structure of Example 1 was 6.8×10⁻⁸A. On the other hand, the drain current flowing in the GaN nitride semiconductor laminated structure of Comparative Example 1 was 3.6×10⁻⁴A. When the drain voltage was 50V, the drain current flowing in the GaN nitride semiconductor laminated structure of Example 1 was 1.9×10⁻⁷ A. On the other hand, the drain current flowing in the GaN nitride semiconductor laminated structure of Comparative example 1 was 1.8×10⁻³ A. Accordingly, it was confirmed that the leak current when the drain voltage was applied was smaller in the case where the insulating film between the source and the drain was made of SiN than in the case where it was made of SiO₂.

### Example 2

A field effect transistor having the structure shown in FIG. 1 was manufactured according to the production steps shown in FIG. 2A through FIG. 2H.

### Comparative Example 2

A field effect transistor was manufactured according to the production steps shown in FIG. 2A through FIG. 2H except that the insulating film 23 was removed after the step of FIG. 2E. Accordingly, this manufactured field effect transistor had a structure different from that of the field effect transistor structured as shown in FIG. 1 in the point that the gate insulating films 14 and the surface insulating films 9 shown in FIG. 1 are formed of only the insulating film 24.

### Measurement of Gate Withstand Voltage

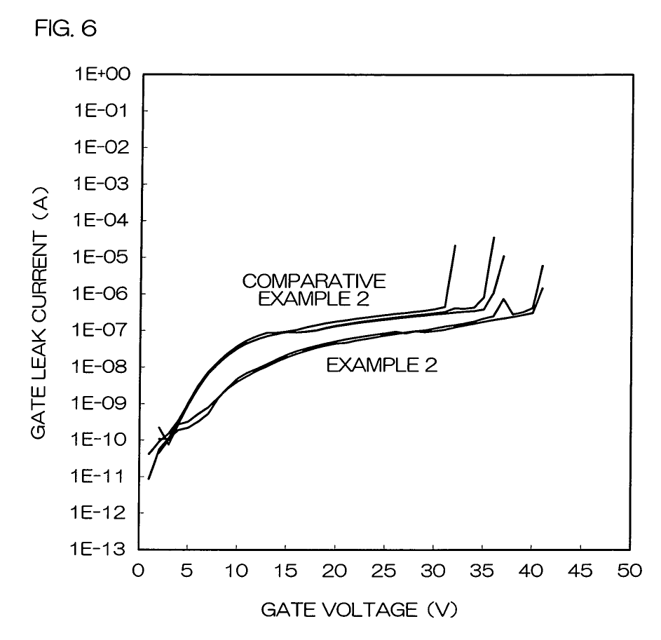

In the field effect transistors of Example 2 and Comparative example 2, first, a bias voltage (drain voltage) of 0V was applied between the source and the drain. From the state where the drain voltage was applied, a bias voltage (gate voltage) being positive to the potential of the source electrode regarded as a reference potential was applied to the gate electrode. A leak current (gate leak current) when the value of this gate voltage was changed was measured. The results of measurement are shown in FIG. 6. As shown in FIG. 6, when the gate voltage was 10V, the gate leak current flowing in the field effect transistor of Example 2 was 4.9×10⁻⁹ A. On the other hand, the gate leak current flowing in the field effect transistor of Comparative example 2 was 3.3×10⁻⁸ A. When the gate voltage was 20V, the gate leak current flowing in the field effect transistor of Example 2 was 5.2×10⁻⁸ A. On the other hand, the gate leak current flowing in the field effect transistor of Comparative example 2 was 1.4×10⁻⁷ A. Accordingly, it was confirmed that the gate leak current was smaller in the case where the mask used for forming the gate trenches was left to increase the thickness of the insulating film on the top surface of the n type GaN layer (n type GaN layer 5 in FIG. 1) (the step of FIG. 2E was performed) than in the case where the thickness was not increased. In addition, the gate withstand voltage was 30V to 35V in Comparative example 2 although it was about 40V in Example 2. From these results, it was confirmed that a more excellent device having a higher withstand voltage and a smaller leak current was obtained in the case of the gate insulating film of the field effect transistor of Example 2.

Although the embodiments of the present invention are described in detail, these embodiments are merely specific examples used for clarifying the technical contents of the present invention. Therefore, the present invention should not be construed as being limited in any way to these specific examples. The spirit and scope of the present invention are limited only by the scope of the appended claims.

This application corresponds to Japanese Patent Application No. 2007-154893 filed with the Japanese Patent Office on Jun. 12, 2007, the full disclosure of which is incorporated herein by reference.

1. A nitride semiconductor device comprising:
a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure formed with a first trench and a second trench, the first trench penetrating the second layer from the third layer and reaching at least the first layer, and the second trench having a side wall extending from the first, second, to third layers and being different from the first trench;
a surface insulating film containing at least silicon nitride formed such that the surface insulating film covers the surface of the first trench;
a gate insulating film formed on the side wall of the second trench such that the gate insulating film extends over the first, second, and third layers; and
a gate electrode formed such that the gate electrode is opposed to the side wall of the second trench with the gate insulating film sandwiched between the gate electrode and the side wall.

2. The nitride semiconductor device according to claim 1, wherein
the gate insulating film is made of a combination of silicon nitride and silicon oxide, and silicon nitride is in direct contact with the side wall of the second trench.

3. A method for producing a nitride semiconductor device comprising:
a laminating step for forming a nitride semiconductor laminated structure having a laminated structure comprising an n type first layer, a second layer containing a p type dopant, and an n type third layer, each layer of the laminated structure made of a group III nitride semiconductor;
a first trench forming step for forming a first trench penetrating the second layer from the third layer and reaching at least the first layer;
a surface insulating film forming step for forming a surface insulating film containing at least silicon nitride so as to cover the surface of the first trench;
a second trench forming step for forming a second trench having a side wall extending from the first, second, to third layers;
a gate insulating film forming step for forming a gate insulating film on the side wall of the second trench so as to extend over the first, second, and third layers; and
a gate electrode forming step for forming a gate electrode so as to be opposed to the side wall of the second trench with the gate insulating film sandwiched between the gate electrode and the side wall.

4. The method for producing a nitride semiconductor device according to claim 3, wherein
the second trench forming step includes a step of forming the second trench by etching using a mask containing at least silicon nitride formed so as to cover at least the surface of the first trench, and
the surface insulating film forming step is a step of forming the surface insulating film including the mask used for forming the second trench.

5. The method for producing a nitride semiconductor device according to claim 4, wherein
the third layer has a top surface parallel to a lamination interface in the nitride semiconductor laminated structure,
the mask is formed so as to cover the top surface, and
the mask covering the top surface is left after the second trench forming step.

6. The method for producing a nitride semiconductor device according to claim 4, wherein
the mask includes a silicon nitride film in contact with the surface of the first trench.

7. The method for producing a nitride semiconductor device according to claim 4, further comprising:
a step of wet etching a surface portion of the mask after the second trench forming step.
